(19) United States
(12) Patent Application Publication
(10) Pub. No.: US 2026/0088117 A1
(43) Pub. Date: Mar. 26, 2026

(54) SYNCHRONIZATION POINTS BASED PARAMETER TUNING IN A STORAGE DEVICE

(71) Applicant: Sandisk Technologies, Inc., Milpitas, CA (US)

(72) Inventors: AKHILESH YADAV, Bangalore (IN); AMIT SHARMA, Bangalore (IN)

(73) Assignee: Sandisk Technologies, Inc., Milpitas, CA (US)

(21) Appl. No.: 18/894,234

(22) Filed: Sep. 24, 2024

(51) Int. Cl. G11C 29/12; G11C 29/36

(52) U.S. Cl. CPC G11C 29/12015; G11C 29/36

(57) ABSTRACT

A storage device may maintain consistent guaranteed performance throughout the life span of the storage device. The storage device includes a data path from a host to a memory device and the data path includes sync points at components along the data. A calibrated time between adjacent sync points on a data path is measured and stored. During use, a controller determines that an event triggering less than the guaranteed performance on the storage device has occurred. The controller measures the calibrated time against a current time associated with the adjacent sync points. When the controller determines that a variance exists between the calibrated time and the current time, the controller applies a corrective measure to retune a data path parameter. The controller uses the retuned parameter to test a calibrated timer on the data path to maintain the guaranteed quality-of-service of the storage device.

### BACKGROUND OF THE INVENTION

A storage device may be communicatively coupled to a host and to non-volatile memory including, for example, a NAND flash memory device on which the storage device may store data received from the host. The storage device may include multiple processing units, clock oscillators, hardware accelerators, NAND Trims, and other configurable hardware and software components. The storage device may be designed to meet predefined performance guarantees, wherein performance thresholds associated with components in the data path (i.e., the path between the host and the memory device) may be determined during the design and manufacture phase. For example, a global address table (GAT) delta eviction threshold, the read scrub frequency, a data retention indication threshold, a data retention detection threshold, the number of buffers, the thresholds for some NAND maintenance tasks, and other performance thresholds, may be determined during the design and manufacture phase of the storage device based on marketing requirements and/or available information and resources.

Prior to being released in the market, the storage device may be tested based on assumed market conditions. During the design and testing phases, it may be difficult to determine some changes that may occur in the firmware over time. For example, external factors such as aging and degradation of electronic components, including transistors and interconnects, may affect the performance characteristics of the storage device, including signal propagation delays, possibly resulting in changes in the direct memory access rate. Temperature variations, another external factor, may also affect the conductivity and resistance of materials within circuits and temperature changes may impact the signal timing and hence the data transfer rates. Other external environmental factors such as humidity, pressure, and/or vibrations may also impact the electrical properties of circuits and, consequently, data transfer rates. Manufacturing variability during the manufacture of, for example, different lots of memory devices, may introduce variations in component characteristics, which may lead to slight differences in signal timings and data transfer rates between individual devices. The length of interconnects and traces may also introduce signal propagation delays, which may impact data transfer rates, especially at higher frequencies.

As such, if the base assumptions made during testing of the storage device change while the storage device is in use or if a new variable is introduced in the overall system, the performance of the storage device, mainly write/read performance, may not match the performance guarantees of the storage device. Furthermore, mostly towards the middle or end of life of the storage device, the overall performance of the storage device may be reduced due, for example, to NAND errors and exception handling. The overall performance of the storage device may also be reduced due to, for example, changes in the system clock tuning as the storage device ages or experiences ambient changes. For example, hardware accelerators and the clocks for other hardware and software components may vary, for example, from ten to twenty percent as the storage device ages or experiences ambient/environmental changes. These ambient conditions or environmental situations that may cause changes to the system clock may be difficult to simulate in labs or in any other modelling methods performed on the data path during the manufacture/testing phase of the storage device.

In an example where aging or experiencing of ambient/environmental conditions causes changes in the system clock tuning, a host timeout may occur during the device verification testing (DVT) qualification due to variance in the interface parameters on the physical layer. In another example, a NAND room temperature data retention (RTDR) issue may occur, wherein drives affected by RTDR may show more than sixty percent reduction in the sustained performance due to large number of blocks being marked for read scrub. This may cause the flash translation layer data path scheduling and time slicing algorithm to function incorrectly and result in the number of read scrub operations being too many to maintain a balance with the host operations. There is no mechanism in current storage devices to measure and correct/retune data path parameters in-order to meet the expected product performance throughout the life of the storage device.

### SUMMARY OF THE INVENTION

In some implementations, the storage device may maintain consistent guaranteed performance throughout its life span. The storage device may include a memory device to store data and a data path from a host to the memory device. The data path may include sync points at points along the data path. A controller on the storage device may determine when a variance is introduced on the data path. The controller may measure a current time between adjacent sync points against a calibrated time associated with the adjacent sync points. The controller may calculate a corrected parameter value to detect a sync point parameter and apply a corrective measure to retune the sync point parameter. The controller may use the retuned sync point parameter to test a calibrated timer on the data path and maintain the guaranteed quality-of-service of the storage device.

In some implementations, a method is provided on a storage device for maintaining consistent guaranteed performance throughout the life span of a storage device. The method includes determining when a variance is introduced on a data path including sync points at components along the data path. The method also includes measuring a current time between adjacent sync points against a calibrated time associated with the adjacent sync points. The method further includes calculating a corrected parameter value to detect a sync point parameter, applying a corrective measure to retune the sync point parameter, and using a retuned sync point parameter to test a calibrated timer on the data path and maintain a guaranteed quality-of-service of the storage device.

In some implementations, a method is provided on a storage device for maintaining consistent guaranteed performance throughout the life span of a storage device. The method includes measuring a calibrated time between adjacent sync points on a data path. The method also includes determining that an event triggering less than the guaranteed performance on the storage device has occurred and measuring the calibrated time against a current time associated with the adjacent sync points. The method further includes determining that a variance exists between the calibrated time and the current time, applying a corrective measure to retune a parameter, and using the retuned parameter to test a calibrated timer on the data path and maintain a guaranteed quality-of-service of the storage device.

### BRIEF DESCRIPTION OF THE DRAWINGS

FIG. 1 is a schematic block diagram of an example system in accordance with some implementations.

FIG. 2 is an example block diagram showing a data path with sync points in accordance with some implementations.

FIG. 3 is an example flow diagram for recalibrating data path parameters based on timing between sync points to ensure consistent guaranteed performance throughout the life span of a storage device in accordance with some implementations.

FIG. 4 is another example flow diagram for recalibrating data path parameters based on timing between sync points to ensure consistent guaranteed performance throughout the life span of a storage device in accordance with some implementations.

FIG. 5 is a diagram of an example environment in which systems and/or methods described herein are implemented.

FIG. 6 is a diagram of example components of one or more devices of FIG. 1.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of implementations of the present disclosure.

The apparatus and method components have been represented where appropriate by conventional symbols in the drawings, showing those specific details that are pertinent to understanding the implementations of the present disclosure so as not to obscure the disclosure with details that will be readily apparent to those of ordinary skill in the art.

### DETAILED DESCRIPTION OF THE INVENTION

The following detailed description of example implementations refers to the accompanying drawings. The same reference numbers in different drawings may identify the same or similar elements.

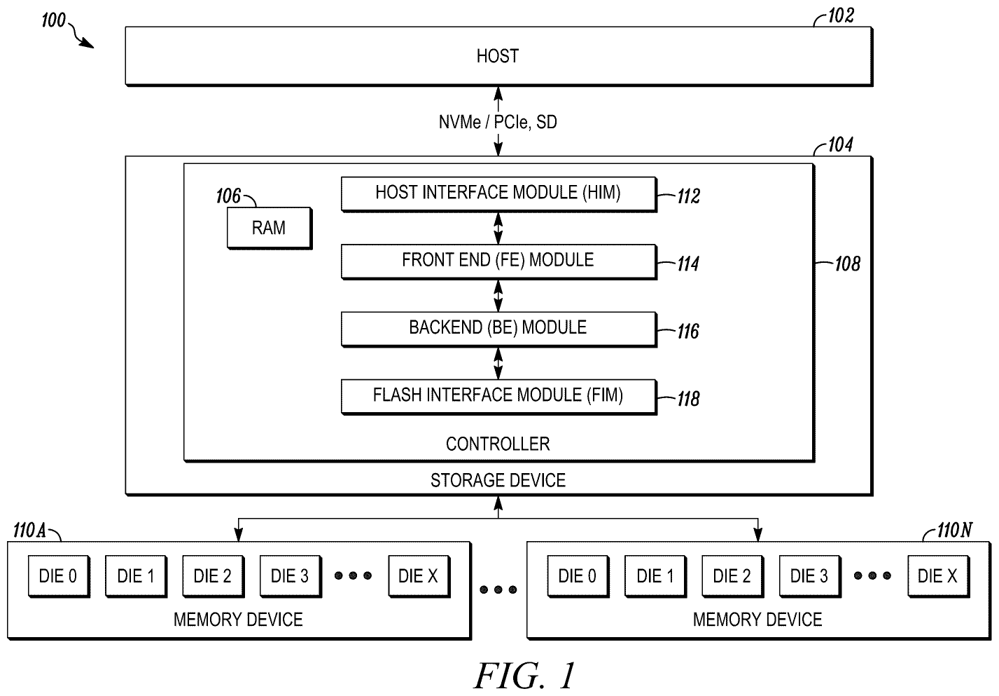

FIG. 1 is a schematic block diagram of an example system in accordance with some implementations. System 100 includes a host 102 and a storage device 104 that may be in the same physical location as components on a single computing device or on different computing devices that are communicatively coupled. Storage device 104, in various implementations, may be disposed in one or more different locations relative to the host 102 and storage device 104 may communicate with host 102 over a peripheral component interconnect express (PCIe) protocol and the like. Host 102 may include additional components (not shown in this figure for the sake of simplicity).

Storage device 104 may include a random-access memory (RAM) 106, a controller 108, one or more non-volatile memory devices 110a-110n (referred to herein as the memory device(s) 110), a host interface module (HIM) 112, a front end (FE) module 114, a backend (BE) module 116, and a flash interface module 118. Storage device 104 may be, for example, a solid-state drive (SSD). RAM 106 may be static RAM (SRAM) or dynamic RAM (DRAM) that may be used to store information used on storage device 104.

Controller 108 may interface with host 102 and process foreground operations including instructions transmitted from host 102. For example, controller 108 may read data from and/or write to memory device 110 based on instructions received from host 102. Controller 108 may also execute background operations to manage resources on memory device 110. For example, controller 108 may monitor memory device 110 and may execute garbage collection, read scrub, and other relocation functions per internal relocation algorithms to refresh, recycle, and/or relocate the data on memory device 110.

Memory device 110 may be flash based. For example, memory device 110 may be a NAND or NOR flash memory that may be used for storing host and control data over the operational life of memory device 110. Memory device 110 may include multiple dies (for example, DIE 0-DIE X) for storing the data. Data may be stored in blocks on the dies in various formats, with the formats being defined by the number of bits that may be stored per memory cell. Memory device 110 may be included in storage device 104 or may be otherwise communicatively coupled to storage device 104.

The data path for read/write operations from host 102 and for management data operations carried out by controller 108 may pass through host interface module 112, front end module 114, backend module 116, and flash interface module 118. Storage device 104 may include sync points throughout the data path, including at hardware accelerators, firmware queues, and/or scheduling points.

At an initial period during the manufacture/testing of storage device 104, the time between adjacent sync points may be calibrated and the calibrated time may be stored in a configuration table. The total calibrated time may also be stored in the configuration table. The calibrated times may be used as timing thresholds. During use of storage device 104, when data is being transmitted along the data path, a timing threshold may be compared against an associated current time between adjacent sync points in the data path to mitigate against changes in timing in the data path that may occur due to, for example, external factors such as aging and/or environmental conditions.

Consider a case wherein as memory device 110 and/or storage device 104 age and small shifts occur on the system clock, the read/write timings may change, likely deteriorating the read/write performance of storage device 104 and causing storage device 104 to not meet quality-of-service guarantees during later stages in the product life span. During use of storage device 104, controller 108 may determine whether or not a variance, P(variance), has been introduced. P(variance) may be the variance in the value of a parameter from an original calibrated value and P(variance) may be more than an expected variance per the guaranteed quantity of service. If controller 108 determines that there is P(variance) when data is being transmitted through the data path, controller 108 may measure the current time between adjacent sync points against the calibrated time between the adjacent sync points.

For example, when shifting of the system clock occurs, controller 108 may determine that a delay has been added between two sync points, for example, backend module 116 and flash interface module 118. Controller 108 may identify the timing variance between the calibrated time between backend module 116 and flash interface module 118 and the current time between backend module 116 and flash interface module. If the timing variance, P(variance), is more than an expected variance as per the guaranteed quality-of-service, controller 108 may calculate a corrected parameter value P(decision) to detect and apply one or more corrective measures to retune one or more sync point parameters and/or timers such that subsequent data path cycles may maintain the guaranteed quality-of-service of storage device 104.

In an implementation, controller 108 may determine whether or not to change and/or re-tune one or more sync point parameters and/or timers using variables P(original), k, and P(variance), wherein P(original), k, and P(variance) may be configured based on the type of storage device 104. P(original) may be an original calibrated value obtained prior to the initial use of storage device 104 and k may be a sensitivity coefficient based on the category of storage device 104 for faster or slower correction. The sensitivity factor, k, may trigger a corrective measure earlier than a normal correction cycle if, for example, k is greater than one.

When controller 108 identifies a timing variance above a predefined tolerance which may impact the calibrated data path throughput and the guaranteed quality-of-service throughout, controller 108 may execute a transfer function to obtain P(decision) and detect and correct one or more sync point parameters and/or timers. P(decision) may be equal to P(original)+k*P(variance). Based on the value of P(decision), controller 108 may apply one or more corrective measures to correct one or more sync point parameters. The corrective measure may include predefined decisions, run-time learning, and/or retuning of one or more data path parameters. Using the corrected parameter(s), controller 108 may retest the calibrated timers to ensure that the corrected parameter(s) may result in the guaranteed quality-of-service throughout. As such, to achieve consistent guaranteed quality-of-service throughout for a product life cycle, the sync points may be used to determine when to re-calibrate the data path parameters and correct variations in the data path clock and/or timing related parameters which may occur, for example, due to the changes in the environmental conditions and/or aging.

In an implementation, controller 108 may choose a first parameter with a predefined value to optimize usage of storage device 104. However, if a dependent parameter changes, then usage of the first parameter may not result in the guaranteed quantity of service. Consider an example where controller 108 chooses a predefined high BER threshold (first parameter) for background operations. If an unpredicted behavior in the data retention in a memory node causes more blocks in memory 110 to show a high bit error rate (BER) signature, the default handling would be for controller 108 to perform background operations. During the background operations, the high BER blocks would be relocated so that the host data may be corrected.

However, in this example, as a result of a large number of blocks being added in the relocation queue, data relocation may affect the host data throughput, likely resulting in lower write/read performance than is guaranteed on storage device 104. To maintain the guaranteed write/read performance on storage device 104, controller 108 may monitor the sync points and may identify that an event triggering less than the guaranteed performance on the storage device has occurred. Controller 108 may then compare the current time between adjacent sync points against the calibrated time between the adjacent sync points. When controller 108 detects that the high BER blocks added in the queue are causing is a timing variance between sync points and that the timing variance is greater than an expected variance as per the guaranteed quality of service, controller 108 may calculate a value for P(decision), and based on the P(decision) value, apply a corrective measure to retune a data path clock and/or timing related parameters (including, for example, the first parameter). For example, controller 108 may apply a corrective measure to retune the high BER threshold such that the high BER signature blocks may be corrected in idle time, without compromising the host sustained performance.

Storage device 104 may perform these processes based on a processor, for example, controller 108 executing software instructions stored by a non-transitory computer-readable medium, such as storage component 110. As used herein, the term “computer-readable medium” refers to a non-transitory memory device. Software instructions may be read into storage component 110 from another computer-readable medium or from another device. When executed, software instructions stored in storage component 110 may cause controller 108 to perform one or more processes described herein. Additionally, or alternatively, hardware circuitry may be used in place of or in combination with software instructions to perform one or more processes described herein. Thus, implementations described herein are not limited to any specific combination of hardware circuitry and software. System 100 may include additional components (not shown in this figure for the sake of simplicity). FIG. 1 is provided as an example. Other examples may differ from what is described in FIG. 1.

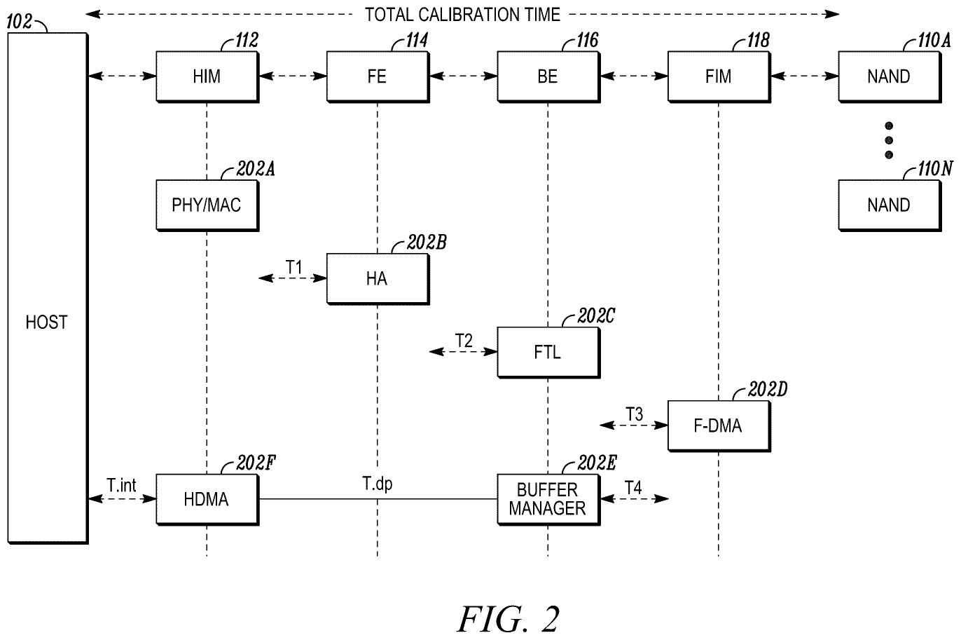

FIG. 2 is an example block diagram showing a data path with sync points in accordance with some implementations. The data path for read/write operations from host 102 and for background operations carried out by controller 108 may pass through points between host interface module 112, front end module 114, backend module 116, and flash interface module 118 including firmware queues and scheduling points. Sync points may be placed at various points throughout the data path. For example, a sync point may be placed at the physical/media access control (PHY/MAC) layer 202a, a sync point may be placed at a hardware accelerator (HA) 202b, a sync point may be placed at a flash translation layer (FTL) 202c, a sync point may be placed at a flash-direct memory access (F-DMA) 202d, a sync point may be placed at a buffer manager 202e, and a sync point may be placed at a host direct memory access (HDMA) 202f. The times (T1-T4, T.dp, and T.int) between two adjacent sync points may be calibrated and stored in a configuration table (not shown) prior to initial use of storage device. A total calibration time may also be stored in the configuration table. The calibration times may be considered as timing thresholds to compare and mitigate variance due to change based on for example, aging and degradation, temperature, manufacturing variability, environmental conditions, and/or interconnect length.

If, for example, a delay is added to the data flow between backend module 116 and flash interface module 118, controller 108 may measure the current time at T3 to the calibrated time at T3, and when controller 108 detects a P(variance) between the current time at T3 and the calibrated time at T3, controller 108 may apply a corrective measure to retune one or more parameters and/or timers so that subsequent data paths may fall within the guaranteed quality-of-service set for storage device 104. As indicated above FIG. 2 is provided as an example. Other examples may differ from what is described in FIG. 2.

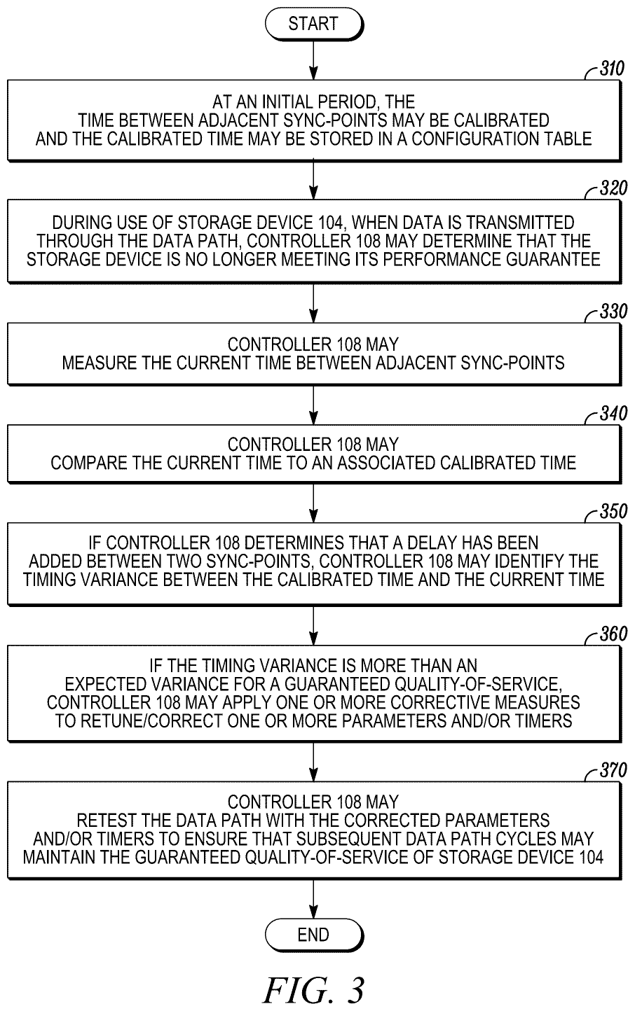

FIG. 3 is an example flow diagram for recalibrating data path parameters based on timing between sync points to ensure consistent guaranteed performance throughout the life span of a storage device in accordance with some implementations. At 310, at an initial period, the time between adjacent sync points may be calibrated and the calibrated time may be stored in a configuration table. At 320, during use of storage device 104, when data is transmitted through the data path, controller 108 may determine that the storage device is no longer meeting its performance guarantee. At 330, controller 108 may measure the current time between adjacent sync points. At 340, controller 108 may compare the current time to an associated calibrated time. At 350, if controller 108 determines that a delay has been added between two sync points, controller 108 may identify the timing variance between the calibrated time and the current time. At 360, if the timing variance is more than an expected variance for a guaranteed quality-of-service, controller 108 may apply one or more corrective measures to retune/correct one or more parameters and/or timers. At 370, controller 108 may retest the data path with the corrected parameters and/or timers to ensure that subsequent data path cycles may maintain the guaranteed quality-of-service of storage device 104. As indicated above FIG. 3 is provided as an example. Other examples may differ from what is described in FIG. 3.

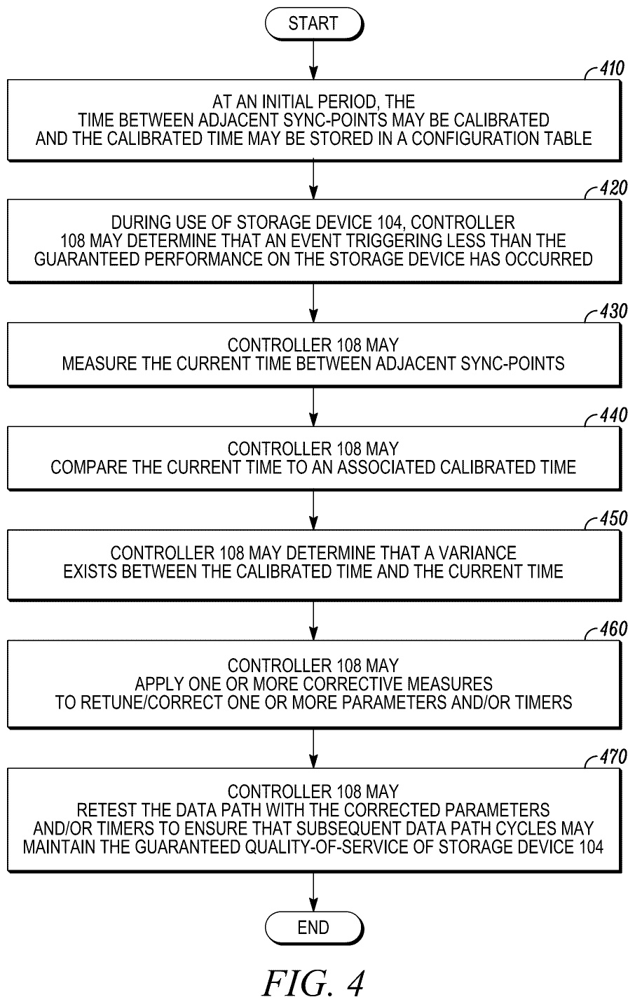

FIG. 4 is another example flow diagram for recalibrating data path parameters based on timing between sync points to ensure consistent guaranteed performance throughout the life span of a storage device in accordance with some implementations. At 410, at an initial period, the time between adjacent sync points may be calibrated and the calibrated time may be stored in a configuration table. At 420, during use of storage device 104, controller 108 may determine that an event triggering less than the guaranteed performance on the storage device has occurred. At 430, controller 108 may measure the current time between adjacent sync points. At 440, controller 108 may compare the current time to an associated calibrated time. At 450, controller 108 may determine that a variance exists between the calibrated time and the current time. At 460, controller 108 may apply one or more corrective measures to retune/correct one or more parameters and/or timers. At 470,. As indicated above FIG. 4 is provided as an example. Other examples may differ from what is described in FIG. 4.

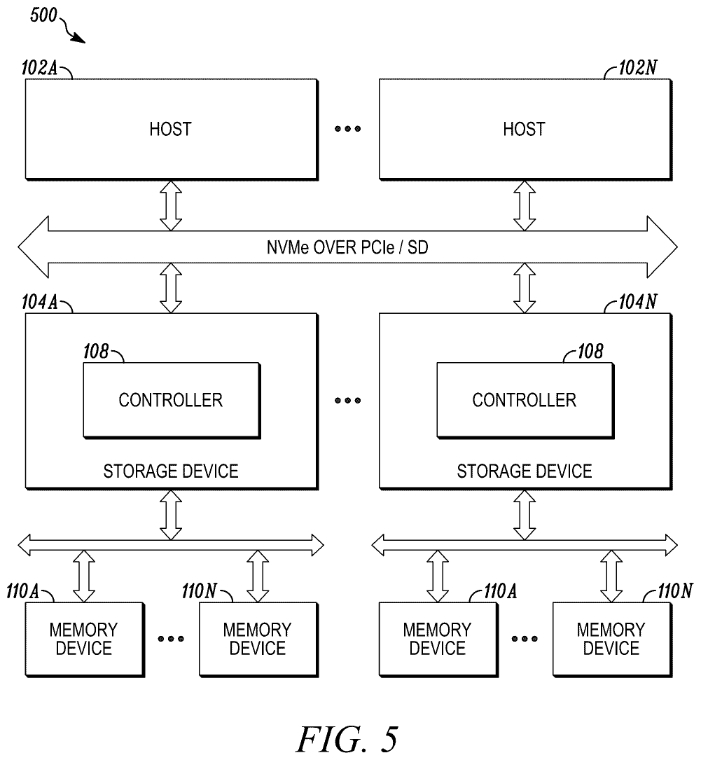

FIG. 5 is a diagram of an example environment in which systems and/or methods described herein are implemented. As shown in FIG. 5, Environment 500 may include hosts 102-102n (referred to herein as host(s) 102), and one or more storage devices 104a-104n (referred to herein as storage device(s) 104). Storage device 104 may include a controller 108 to recalibrate data path parameters based on timing between sync points to ensure consistent guaranteed performance throughout the life span of storage device 104. Hosts 102 and storage devices 104 may communicate via Non-Volatile Memory Express (NVMe) over peripheral component interconnect express (PCI Express or PCIe), SD, or the like.

Devices of Environment 500 may interconnect via wired connections, wireless connections, or a combination of wired and wireless connections. For example, the network in FIG. 5 may include NVMe over Fabric(NVMe-oF) Internet Small Computer Systems Interface(iSCSI), Fibre Channel (FC), Fibre Channel Over Ethernet (FCoE) connectivity and any another type of next-generation network and storage protocols, a local area network (LAN), a wide area network (WAN), a metropolitan area network (MAN), a private network, an ad hoc network, an intranet, the Internet, a fiber optic-based network, a cloud computing network, or the like, and/or a combination of these or other types of networks.

The number and arrangement of devices and networks shown in FIG. 5 are provided as an example. In practice, there may be additional devices and/or networks, fewer devices and/or networks, different devices and/or networks, or differently arranged devices and/or networks than those shown in FIG. 5. Furthermore, two or more devices shown in FIG. 5 may be implemented within a single device, or a single device shown in FIG. 5 may be implemented as multiple, distributed devices. Additionally, or alternatively, a set of devices (e.g., one or more devices) of Environment 500 may perform one or more functions described as being performed by another set of devices of Environment 500.

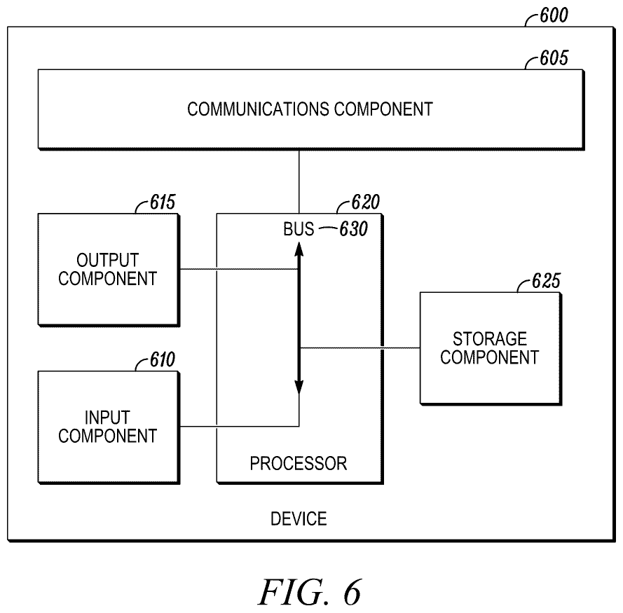

FIG. 6 is a diagram of example components of one or more devices of FIG. 1. In some implementations, host 102 may include one or more devices 600 and/or one or more components of device 600. Device 600 may include, for example, a communications component 605, an input component 610, an output component 615, a processor 620, a storage component 625, and a bus 630. Bus 630 may include components that enable communication among multiple components of device 600, wherein components of device 600 may be coupled to be in communication with other components of device 600 via bus 630.

Input component 610 may include components that permit device 600 to receive information via user input (e.g., keypad, a keyboard, a mouse, a pointing device, and a network/data connection port, or the like), and/or components that permit device 600 to determine the location or other sensor information (e.g., an accelerometer, a gyroscope, an actuator, another type of positional or environmental sensor). Output component 615 may include components that provide output information from device 600 (e.g., a speaker, display screen, and network/data connection port, or the like). Input component 610 and output component 615 may also be coupled to be in communication with processor 620.

Processor 620 may be a central processing unit (CPU), a graphics processing unit (GPU), an accelerated processing unit (APU), a microprocessor, a microcontroller, a digital signal processor (DSP), a field-programmable gate array (FPGA), an application-specific integrated circuit (ASIC), or another type of processing component. In some implementations, processor 620 may include one or more processors capable of being programmed to perform a function. Processor 620 may be implemented in hardware, firmware, and/or a combination of hardware and software.

Storage component 625 may include one or more memory devices, such as random-access memory (RAM 106), read-only memory (ROM), and/or another type of dynamic or static storage device (e.g., a flash memory, a magnetic memory, and/or optical memory) that stores information and/or instructions for use by processor 620. A memory device may include memory space within a single physical storage device or memory space spread across multiple physical storage devices. Storage component 625 may also store information and/or software related to the operation and use of device 600. For example, storage component 625 may include a hard disk (e.g., a magnetic disk, an optical disk, and/or a magneto-optic disk), a solid-state drive (SSD), a compact disc (CD), a digital versatile disc (DVD), a floppy disk, a cartridge, a magnetic tape, CXL device and/or another type of non-transitory computer-readable medium, along with a corresponding drive.

Communications component 605 may include a transceiver-like component that enables device 600 to communicate with other devices, such as via a wired connection, a wireless connection, or a combination of wired and wireless connections. The communications component 605 may permit device 600 to receive information from another device and/or provide information to another device. For example, communications component 605 may include an Ethernet interface, an optical interface, a coaxial interface, an infrared interface, a radio frequency (RF) interface, a universal serial bus (USB) interface, a Wi-Fi interface, and/or a cellular network interface that may be configurable to communicate with network components, and other user equipment within its communication range. Communications component 605 may also include one or more broadband and/or narrowband transceivers and/or other similar types of wireless transceiver configurable to communicate via a wireless network for infrastructure communications. Communications component 605 may also include one or more local area network or personal area network transceivers, such as a Wi-Fi transceiver or a Bluetooth transceiver.

Device 600 may perform one or more processes described herein. For example, device 600 may perform these processes based on processor 620 executing software instructions stored by a non-transitory computer-readable medium, such as storage component 625. As used herein, the term “computer-readable medium” refers to a non-transitory memory device. Software instructions may be read into storage component 625 from another computer-readable medium or from another device via communications component 605. When executed, software instructions stored in storage component 625 may cause processor 620 to perform one or more processes described herein. Additionally, or alternatively, hardware circuitry may be used in place of or in combination with software instructions to perform one or more processes described herein. Thus, implementations described herein are not limited to any specific combination of hardware circuitry and software.

The number and arrangement of components shown in FIG. 6 are provided as an example. In practice, device 600 may include additional components, fewer components, different components, or differently arranged components than those shown in FIG. 6. Additionally, or alternatively, a set of components (e.g., one or more components) of device 600 may perform one or more functions described as being performed by another set of components of device 600.

The foregoing disclosure provides illustrative and descriptive implementations but is not intended to be exhaustive or to limit the implementations to the precise form disclosed herein. One of ordinary skill in the art will appreciate that various modifications and changes can be made without departing from the scope of the present disclosure as set forth in the claims below. Accordingly, the specification and figures are to be regarded in an illustrative rather than a restrictive sense, and all such modifications are intended to be included within the scope of present teachings.

As used herein, the term “component” is intended to be broadly construed as hardware, firmware, and/or a combination of hardware and software. It will be apparent that systems and/or methods described herein may be implemented in different forms of hardware, firmware, and/or a combination of hardware and software.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set.

No element, act, or instruction used herein should be construed as critical or essential unless explicitly described as such. Also, as used herein, the articles “a” and “an” are intended to include one or more items and may be used interchangeably with “one or more. ” Furthermore, as used herein, the term “set” is intended to include one or more items (e.g., related items, unrelated items, a combination of related items, unrelated items, and/or the like), and may be used interchangeably with “one or more. ” The term “only one” or similar language is used where only one item is intended. Further, the phrase “based on” is intended to mean “based, at least in part, on” unless explicitly stated otherwise.

Moreover, in this document, relational terms such as first and second, top and bottom, and the like, may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, or “contains . . . a” does not, without more constraints, preclude the existence of additional identical elements in the process, method, article, or apparatus that comprises, has, includes, contains the element. The terms “substantially”, “essentially”, “approximately”, “about” or any other version thereof, are defined as being close to as understood by one of ordinary skill in the art, and in one non-limiting implementation, the term is defined to be within 10%, in another implementation within 5%, in another implementation within 1% and in another implementation within 0.5%. The term “coupled” as used herein is defined as connected, although not necessarily directly and not necessarily mechanically. A device or structure that is “configured” in a certain way is configured in at least that way but may also be configured in ways that are not listed.

We claim:

1. A storage device to maintain consistent guaranteed performance throughout a life span of the storage device, the storage device comprises:
a memory device to store data;
a data path from a host to the memory device, wherein the data path includes sync points at components along the data path; and
a controller to determine when a variance is introduced on the data path, measure a current time between adjacent sync points against a calibrated time associated with the adjacent sync points, calculate a corrected parameter value to detect a sync point parameter, apply a corrective measure to retune the sync point parameter, and use a retuned sync point parameter to test a calibrated timer on the data path and maintain a guaranteed quality-of-service of the storage device.

2. The storage device of claim 1, wherein the controller calculates the corrected parameter value by multiplying a sensitivity coefficient to the variance and adding a product to an original calibrated value.

3. The storage device of claim 2, wherein the original calibrated value, the sensitivity coefficient, and the variance are configured based on a storage device type.

4. The storage device of claim 2, wherein the sensitivity coefficient is based on a storage device category and when the sensitivity coefficient is greater than one, the sensitivity coefficient triggers the corrective measure.

5. The storage device of claim 1, wherein the corrective measure includes at least one of predefined decisions, run-time learning, and retuning of at least one data path parameter.

6. The storage device of claim 1, wherein the variance is a variance from an original calibrated value and the variance is more than an expected variance per the quality-of-service guarantee of the storage device.

7. The storage device of claim 1, wherein the sync points are placed at one or more of a host interface module, a front end module, a backend module, a flash interface module, hardware accelerators, firmware queues, and scheduling points.

8. The storage device of claim 1, wherein at an initial period, a time between adjacent sync points is calibrated and stored in a configuration table.

9. The storage device of claim 1, wherein the controller selects a first parameter that is associated with the data path and performs the corrective measure on the first parameter when a dependent parameter changes the guaranteed quality-of-service of the storage device.

10. A method for maintaining consistent guaranteed performance throughout a life span of a storage device, the storage device comprises a controller to execute the method comprising:
determining when a variance is introduced on a data path including sync points at components along the data path;
measuring a current time between adjacent sync points against a calibrated time associated with the adjacent sync points;
calculating a corrected parameter value to detect a sync point parameter;
applying a corrective measure to retune the sync point parameter; and
using a retuned parameter to test a calibrated timer on the data path to maintain a guaranteed quality-of-service of the storage device.

11. The method of claim 10, wherein calculating comprises multiplying a sensitivity coefficient to the variance and adding a product to an original calibrated value.

12. The method of claim 11, further comprising configuring the original calibrated value, the sensitivity coefficient, and the variance based on a storage device type.

13. The method of claim 11, wherein when the sensitivity coefficient is greater than one, triggering the corrective measure.

14. The method of claim 10, wherein applying the corrective measure includes applying at least one of a predefined decision, run-time learning, and retuning of at least one data path parameter.

15. The method of claim 10, further comprising selecting a first parameter that is associated with the data path and performing the corrective measure on the first parameter when a dependent parameter changes the guaranteed quality-of-service of the storage device.

16. A method for maintaining consistent guaranteed performance throughout a life span of a storage device, the storage device comprises a controller to execute the method comprising:
measuring a calibrated time between adjacent sync points on a data path;
determining that an event triggering less than the guaranteed performance on the storage device has occurred;
measuring the calibrated time against a current time associated with the adjacent sync points;
determining that a variance exists between the calibrated time and the current time;
applying a corrective measure to retune a data path parameter; and
using a retuned parameter to test a calibrated timer on the data path to maintain a guaranteed quality-of-service of the storage device.

17. The method of claim 16, wherein determining that the variance exists comprises determining that the variance is more than an expected variance per the quality-of-service guarantee of the storage device.

18. The method of claim 16, further comprising storing the calibrated time in a configuration table.

19. The method of claim 16, further comprising selecting a first parameter that is associated with the data path and performing the corrective measure on the first parameter when a dependent parameter changes the guaranteed quality-of-service of the storage device.

20. The method of claim 16, wherein applying the corrective measure includes applying at least one of predefined decisions, run-time learning, and retuning of at least one data path parameter.
